(19) United States
(12) Patent Application Publication
(10) Pub. No.: US 2008/0218949 A1
(43) Pub. Date: Sep. 11, 2008

(54) ENCLOSURE FOR CONTAINING ONE OR MORE ELECTRONIC DEVICES AND COOLING MODULE

(75) Inventor: Robert W. Hughes, Emsworth (GB)

Correspondence Address: PILLSBURY WINTHROP SHAW PITTMAN, LLP, P.O. BOX 10500, MCLEAN, VA, 22102, US

(73) Assignee: XYRATEX TECHNOLOGY LIMITED, Havant (GB)

(21) Appl. No.: 11/972,255

(22) Filed: Jan. 10, 2008

Related U.S. Application Data
(60) Provisional application No. 60/884,537, filed on Jan. 11, 2007.

(51) Int. Cl. H05K 5/00; H05K 7/20

(52) U.S. Cl. 361/679; 361/707

(57) ABSTRACT

An enclosure for containing one or more electronic devices is disclosed. The enclosure comprises walls defining a channel; an air movement device in the channel, the channel having an air inlet upstream of the air movement device in communication with a first region of the enclosure; and, a pressure chamber in the channel downstream of the air movement device. The air movement device is arranged so as in use to blow air drawn from the air inlet into the pressure chamber. The pressure chamber has an increased resistance to airflow so as to positively pressurise the air flowing therethrough. The pressure chamber has a first air outlet in communication with a second region of the enclosure and a second air outlet in communication with the exterior of the enclosure.

This application claims the benefit of priority to U.S. application Ser. No. 60/884,537, filed Jan. 11, 2007, the content of which is hereby incorporated by reference.

The present invention relates to an enclosure for containing one or more electronic devices and to a cooling module. In preferred embodiments, the present invention relates to storage enclosures for a plurality of disk drives, RAID arrays, SAN or NAS storage, server enclosures and the like, and to cooling modules for such enclosures.

A typical data storage device enclosure is modular, having bays at the front for receiving disk drive assemblies in carriers, and bays at the rear for receiving power supply units (PSUs), cooling modules and various electronics modules providing for example input/output connection to the enclosure, RAID functionality, enclosure management services, etc. However, many other layouts and configurations are possible.

The various components of the enclosure generate heat, which must be removed from the enclosure to keep the operating temperature of the components within acceptable limits or else the performance and reliability of the enclosure will be impaired. Also the trend is to fit more and more components into an enclosure of a given size, thereby increasing the cooling demands for the enclosure. To this end, a cooling air flow is commonly provided through the enclosure and the various bays of the enclosure by one or more air movement devices, such as fans or blowers, within the enclosure.

Conventionally, a “front-to-rear” cooling air flow is used. In such a front-to-rear cooling scheme, the enclosure has apertures in the front face of the enclosure, which allow cooling air to enter the enclosure. Fans are typically located at the rear of the enclosure, so as to draw cooling air through the enclosure and expel the heated air through further apertures or vents at the rear of the enclosure. Placement of apertures, baffles and/or plenums may be used within the enclosure to guide the air through the enclosure in such a way that the cooling air is directed to where it is needed.

In a known cooling arrangement, the cooling fans for the enclosure are incorporated into the power supplies, which are positioned at the sides of the enclosure, with the electronics module bays positioned between the power supplies. The PSU fans provide the front-to-rear cooling airflow through the enclosure. However, this cooling arrangement has the disadvantage that most of the airflow passes through the PSUs and relatively little passes through the electronics modules. The electronics modules can therefore receive inadequate volume and direction of cooling air.

In a refinement of this arrangement, it is also known to have ventilation inlets in the rear faces of the electronics modules. This allows air to be drawn in by the PSU fans from the rear of the enclosure through the vents in order to cool the electronics. However, this arrangement has the disadvantage that the cooling air for the electronics is recirculated from the rear of the enclosure and is thus heated air. This has several undesirable consequences. First, heated air is less effective at cooling the electronics. Also, the overall airflow from the front to the rear of the enclosure is reduced by the recirculation of air, typically by as much as 10 to 15%. This means that less air is available to cool the disk drives in the front of the enclosure. Lastly, the vents in the rear faces of the electronics modules take up additional space from the limited space available, leaving less space available for interconnects and other components.

In another known arrangement, one or more system fans are provided in addition to fans in the PSUs. The system fans are in the main responsible for providing a front-to-rear airflow through the enclosure for cooling the disk drives and the electronics. The PSU fans are responsible for drawing some of this cooling airflow through the PSUs to cool the PSUs. The drawback of this arrangement is that the system fans and PSU fans contend for the same air flow to cool their respective regions of the enclosure. This arrangement also involves additional fans being placed adjacent the rear of the enclosure, visible from the rear of the enclosure, thus leading to increased acoustic noise levels.

According to a first aspect of the present invention, there is provided an enclosure for containing one or more electronic devices, the enclosure comprising: walls defining a channel; an air movement device in the channel, the channel having an air inlet upstream of the air movement device in communication with a first region of the enclosure; and, a pressure chamber in the channel downstream of the air movement device, the air movement device being arranged so as in use to blow air drawn from the air inlet into the pressure chamber, the pressure chamber having an increased resistance to airflow so as to positively pressurise the air flowing therethrough; the pressure chamber having a first air outlet in communication with a second region of the enclosure and a second air outlet in communication with the exterior of the enclosure.

This arrangement allows the first region to be cooled by having the air movement device draw cooling air through the first region and into the channel via the air inlet. The air is then positively pressurised in the pressure chamber. This in effect creates a reservoir of cooling air which can be used as a source of cooling air for other regions of the enclosure.

In this case, the positively pressurised air can be “pushed” into the second region via the first air outlet to supply cooling air for cooling components located in the second region. Air from the pressure chamber can also “escape” from the enclosure via the second air outlet. The escape route preferably has a low resistance to airflow. This can be advantageous in that not all cooling air drawn across the first region is required to be used by the second region; the second region can take as much or as little cooling air from the reservoir as needed. This is advantageous, for example, when the second region has a relatively high resistance to airflow compared to the first region. If the escape route were not provided, then the high resistance of the second region would limit the overall airflow, and therefore limit the airflow in the first region. However, the escape route allows the air movement device to draw as much cooling air as desired across the first region and not be limited by the resistance of the second region, since excess air can escape via the low resistance escape route. The second region can take as much air as it needs without affecting the cooling of the rest of the enclosure. The airflows in the first and second regions are therefore advantageously balanced. Also advantageously, the airflow is from the first region to the second region in turn. Thus competition for air is substantially eliminated or greatly reduced. The cooling scheme can also be compact and make efficient use of the available space in the enclosure, and the limited space at the rear face of the enclosure.

In a preferred embodiment, the first and second regions are isolated from each other so as to prevent movement of air between them other than through the channel. This further accentuates the advantages of balancing airflow and reducing competition for air between the two regions. This also helps prevent undesirable recirculation of air within the enclosure. Said walls may perform the isolation. This has the advantage of allowing a more space-efficient enclosure to be provided.

In a preferred embodiment, the enclosure has a front face and a rear face, the front face having apertures therein in communication with the first region so that, in use, the air movement device draws cooling air in from the front of enclosure through the apertures, through the first region and into the channel through the air inlet. In a preferred embodiment, the second air outlet opens to the exterior of the storage enclosure at the rear of the enclosure. This allows the enclosure to be used in typical 19 inch racks (approx. 48 cm) where it is typical for cooling to be “front-to-rear”.

The air inlet may be towards the rear of the enclosure. This has the advantage that the cooling air may be drawn across substantially the full extent of the first region, entering at the front and exiting to the channel inlet near the rear, thereby providing a supply of cooling air throughout the first region.

The first air outlet may be closer to the front of the enclosure than the air inlet. This allows air to be provided to the second region at a point away from the rear of the enclosure, for example towards the front of the enclosure, or towards the mid-plane of the enclosure, as appropriate depending on the type and layout of the enclosure. This has the advantage that the cooling air supplied to the second region can be allowed to vent to the rear of the enclosure in accordance with common “front-to-rear” cooling schemes, and at the same time pass throughout the second region. In this way, both the first and second enclosures can have localised front-to-rear airflow, whilst the overall enclosure can also have front-to-rear airflow.

The air movement device may be arranged so as in use to blow air towards a face of the pressure chamber, causing the air to change direction, thereby causing said increased resistance to airflow.

The walls defining the channel may be provided by a housing having a generally rectangular box shape, having opposed long side walls, opposed top and bottom walls, and opposed end walls at first and second ends of the housing, the first opening being in one of the long side walls near the first end of the housing, the second opening being in the opposed long side wall at the second end of the housing, the third opening being in the end wall at the first end of the housing, the cooling module comprising a baffle at least partially surrounding the first opening to direct air from the first opening to the air movement device. This provides a form factor that can conveniently be used with common enclosure layouts, where modules may be inserted into/removed from the enclosure through square/rectangular bays in the rear of the enclosure. A connector may be provided on the exterior wall of the second end so that connection can be made to a midplane of the enclosure for supplying power and/or exchanging control/data signals.

The air movement device may be out of sight behind the baffle and/or the housing. This helps minimise acoustic noise levels.

The walls that define the channel, the air movement device and the pressure chamber may be provided by a cooling module that is removable from the enclosure.

In combination, an enclosure as described above and a power supply contained within said second region may be provided, the power supply having an airflow path from the first air outlet to a vent in the power supply at the rear of the enclosure. This allows the power supply to be cooled, whilst maintaining a front-to-rear cooling scheme. The power supply may have an air movement device adjacent its vent for expelling air. In addition to the pressure chamber pushing cooling air into the power supply, this draws cooling air through the power supply, thereby helping the airflow through the power supply, which often has a high resistance to airflow.

In combination, an enclosure as described above and at least one electronics module contained within said first region may be provided, the electronics module having an airflow path in communication with the air inlet. The electronics module may provide functionality to the enclosure of one or more of: an input/output module, a RAID module, and an enclosure management module. This allows the electronics modules to be cooled efficiently.

In combination, an enclosure as described above and at least one disk drive unit may be provided, wherein the enclosure has a disk drive enclosure towards the front of the enclosure for receiving said at least one disk drive unit, said first and second regions being accommodated towards the rear of the enclosure. In such an arrangement, cooling air that is drawn into the enclosure first passes among the disk drive modules, cooling any disk drive assemblies present, before passing to the rear of the enclosure and the first region. Typically a mid-plane separates the front and rear enclosures, having apertures to allow cooling air drawn in at the front of the enclosure to pass to the rear of the enclosure.

According to a second aspect of the present invention, there is provided a cooling module for a data storage device enclosure, the cooling module comprising a housing having an air movement device therein, the housing having: a first opening providing an air inlet, the air movement device being in fluid communication with the air inlet so as to draw air solely via the air inlet; a pressure chamber constructed and arranged so that the air movement device in use blows air drawn from the air inlet into the pressure chamber, the pressure chamber having an increased resistance to airflow so as to positively pressurise the air in the pressure chamber; a second opening in fluid communication with the pressure chamber and providing a first air outlet; and, a third opening in fluid communication with the pressure chamber and providing a second air outlet.

The air movement device may be a fan or a blower.

Embodiments of the present invention will now be described by way of example with reference to the accompanying drawings, in which:

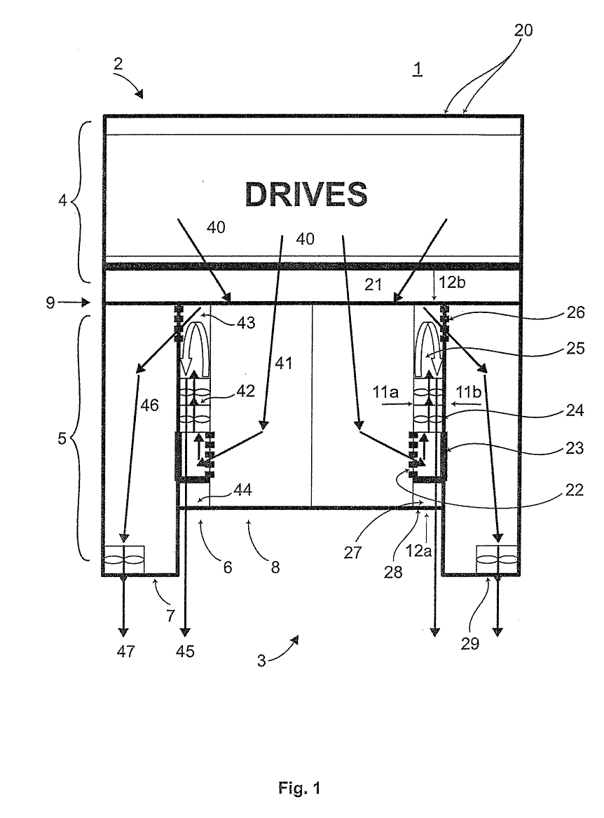

FIG. 1 shows a sectional view of an example of a storage enclosure in accordance with an embodiment of the present invention viewed from above showing the airflow within the enclosure schematically; and,

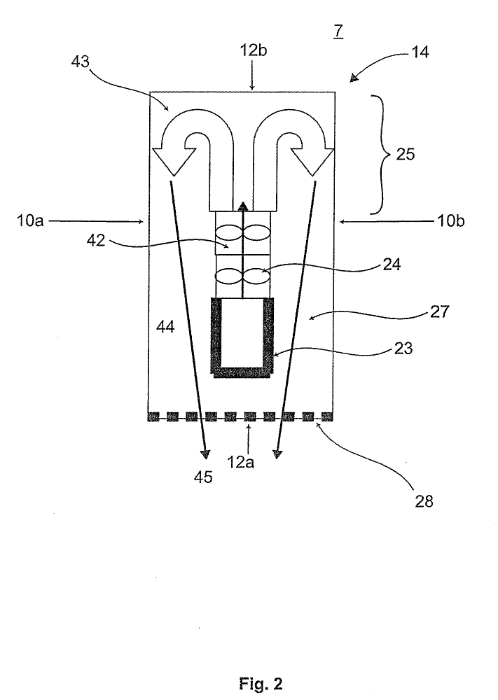

FIG. 2 shows a sectional view of the cooling module of FIG. 1 viewed from the side.

FIG. 1 shows a sectional view of an example of a storage enclosure 1 in accordance with an embodiment of the present invention viewed from the top, showing the air flow within the enclosure 1 schematically. The enclosure 1 has a front face 2 and a rear face 3. As is conventional, the enclosure 1 has a drive enclosure 4 at the front of the enclosure, wherein a plurality of disk drive assemblies in carriers (not shown in detail) are received into bays in the drive enclosure 4. The rear enclosure 5 comprises a number of bays into which can be received two cooling modules 6, two power supply units 7, and two electronic modules 8. A mid-plane 9 is situated within the enclosure 1 between the drive enclosure 4 and the rear enclosure 5. The mid-plane 9 has connectors by which connection can be made to the plurality of disk drives in the disk drive enclosure 4 and to the various modules in the rear enclosure 5 so that power supply and control and data signals can be distributed between the various modules. The enclosure 1 also has rails (not shown) at either side to allow the enclosure 1 to be mounted in a rack, such as a common standard 19 inch (approx. 48 cm) rack, with the front and rear faces 3,4 of the enclosure 1 accessible by an operator.

The power supply units 7 are typically the heaviest components in the enclosure 1, and are therefore naturally situated at either side of the enclosure 1, so as to receive support from the rack in which the enclosure 1 is mounted. The electronic modules 8 can implement a variety of functionality for the enclosure 1. The electronics modules 8 include at least one input/output (I/O) module to allow external connection to be made to the enclosure 1 by a host computer or server. The electronics modules 8 can also include enclosure management modules for monitoring the performance of the enclosure 1, and various types of application modules to implement particular functionality of the enclosure 1, such as organising the drives as a JBOD (“just a bunch of disks”), a RAID array, a SNA (storage network array) arrangement, etc. Often modules are duplicated in order to provide redundancy in case of failure, and removable to allow hot-swapping.

The front face 2 of the enclosure 1 has a plurality of apertures 20 around each drive bay. This allows cooling air 40 to enter the enclosure 1 and flow around and between the disk drive units, thereby cooling them. The mid-plane 9 has a series of apertures 21 which allow cooling air 40,41 to pass from the drive enclosure 4 to the rear enclosure 5. The electronics modules 8 typically have a circuit board which is relatively unenclosed by any housing, e.g. positioned in a tray. This allows cooling air 41 to pass over the circuit board cooling the components thereon.

Each cooling module 6 comprises a generally rectangular box shape housing 14, having top and bottom walls 10a,10b, first and second opposed long side walls 11a,11b, and first and second opposed end walls 12a,12b. When positioned in the enclosure 1, the top and bottom walls 10a,10b of the housing 14 abut the interior walls of the enclosure 1. Each cooling module 6 is positioned between a respective electronics module 8 and power supply unit 7, such that the first long side wall 11a is adjacent the electronics module 8 and the second long side wall 11b is adjacent the power supply unit 7. The first end wall 12a is adjacent the rear 3 of the enclosure 1 and the second end wall 12b is adjacent the mid-plane 9. The cooling module 6 is releasably mountable in the enclosure 1 by sliding in from the rear 3 of the enclosure 1. The cooling module 6 has connectors (not shown) on its second end wall 12b for connecting to the mid-plane 9, so the cooling module 6 can receive power from and exchange control signals with the enclosure 1.

The cooling module 6 has an air inlet 22 in the first long side wall 11a of the housing 14. The inlet 22 is located towards the rear 3 of the enclosure 1. Within the housing 14 the inlet 22 is partially surrounded by a baffle 23, so as to direct the inlet air away from the rear 3 of the enclosure 1 towards the mid-plane 9 of the enclosure 1 and towards a fan unit 24 within the housing 14. The fan 24 is arranged to receive air from the inlet 22 and to blow the air generally in the direction towards the mid-plane 9, i.e. towards the second end face 12b of the housing 14.

Immediately downstream of the fan 24 is a pressure chamber 25, which is formed by the end of the housing 14 of the cooling module 6 that is adjacent the mid-plane 9, i.e. second end face 12b, and the surrounding portions of the adjacent faces 10a,b; 11a,b. The pressure chamber 25 has a first outlet 26 provided by the second long side wall 11b of the housing 14. This outlet 26 is formed near the mid-plane 9 of the enclosure, and is provided in the long side wall opposite first long side wall 11a in which the air inlet 22 is provided.

The cooling module 6 also has a surplus air path 27 by which air can leave the pressure chamber 25. This path 27 is formed between the walls 10a,b; 11a,b of the housing 14 and the outside walls of the fan unit 24 and baffle 23. As can best be seen from FIG. 2, the path 27 ends in an outlet vent 28 provided in the first end face 12a of the cooling module 6 opening to the rear 3 of the enclosure 1. This path 27 provides a low resistance path by which surplus air 44 can leave the pressure chamber 25 and exit the enclosure 1 at the rear 3.

Thus, as described above, the cooling module provides a channel 23,24,25,27 for movement of air 42,43,44, having an air inlet 22, a first outlet 26 and a second outlet 28.

In use, the fans 24 draw a cooling flow of air into the enclosure 1 via apertures 20. Air 40 passes among the drives in the drive enclosure 4, thereby cooling the drives. Air 41 passes into the rear of the enclosure 5 through the apertures 21 in the mid-plane 9 and passes over the circuit boards and components in the electronic modules 9, thereby cooling the electronics. The air 42 is then drawn into the cooling module 6 by the fan 24 through inlets 22, and is blown into the pressure chamber 25. The air 42 is directed by the fan 24 into the end face of the pressure chamber 25 provided by the second end face 12b of the housing 14. The flow of air 43 is thereby caused change direction and loop back on itself within the pressure chamber 25. Therefore the pressure chamber 25 presents a resistance to the flow of air 43 blown into it by the fan 24. This resistance creates a positively pressurised chamber of air relative to the storage enclosure external ambient at normal atmospheric pressure. The pressure level inside the pressure chamber 25 depends upon the pressure performance of the fan 24 but for a typical enclosure 1, an example of a preferred pressure in the pressure chamber 25 is expected to be about 80 Pa above atmospheric pressure. In any event, for a typical enclosure 1, it is preferred that the pressure in the pressure chamber 25 is at least 20 Pa above atmospheric pressure.

There are two possible paths which the air 43 can take on leaving the pressure chamber 25. First, air 46 can be pushed through outlet vent 26 into the power supply units 7. The power supply unit 7 may be provided in a housing of its own, in which case an aperture is also provided that lines up with the outlet vent 26 so that air can pass from the cooling module 6 to the power supply unit 7. The power supply unit 7 has an air path 46 between outlet vent 26 and the rear face of the power supply 7. The power supply unit 7 has its own fan 29 at its rear face, which assists in drawing cooling air 46 through the PSU housing. The cooling air 46 is vented from the rear 3 of the enclosure 1 in an exhaust flow 47. Thus the cooling of the power supply unit 7 is assisted by the positive pressure chamber 25 pushing air 46 into the housing of the power supply unit 7 and the power supply unit fan 29 pulling air 46 through the housing of the power supply unit 7 and venting air 47 at the rear of the enclosure 3.

The second path by which air can leave the pressurised chamber 25 is via surplus air path 27. Air 43 blown out of fan 24 follows a curved path and flows back round between the sides 10a,b; 11a,b of the housing 14 of the cooling module 6 and the outsides of the fans 24 and baffle 23. Surplus air 45 is then vented out of the rear 3 of the enclosure 1 through vent 28.

In this way, the surplus air path 27 provides a low resistance path by which air 44,45 can pass out of the pressurised chamber 25 and be vented out of the rear 3 of the enclosure 1. The low pressure path 27 allows sufficient air flow through the enclosure 1 from the front face 2 to the rear face 3 so that the drives and electronic modules 8 can be adequately cooled. The power supply units 7 typically have a higher resistance to air flow than other modules in the enclosure 1. The power supply units 7 can draw as much or as little cooling air from the reservoir of air created in the pressure chamber 27 due to the reservoir of cooling air 43 created in the positively pressurised pressure chamber 25.

The cooling module 6 has a small footprint when viewed from the rear 3 of the enclosure. This advantageously provides sufficient cooling to the enclosure 1 without seriously affecting the amount of space available at the rear of the enclosure for interconnects to and from the enclosure 1. In addition, when viewed from the rear of the enclosure 3, the fan 24 is not in direct line of sight, as it is hidden behind the baffle 23 and/or the housing 14 of the cooling module 6 from this position. This arrangement therefore helps reduce the acoustic noise levels created by the operation of the fans 24.

In the presently described example, the cooling modules 6 are removable modules. However in other embodiments the cooling modules 6 could be incorporated integrally into the power supply units 7 to form one single unit. Alternatively the cooling units can be formed integrally with the enclosure 1.

Embodiments of the present invention have been described with particular reference to the examples illustrated. However, it will be appreciated that variations and modifications may be made to the examples described within the scope of the present invention.

1. An enclosure for containing one or more electronic devices, the enclosure comprising:
walls defining a channel;
an air movement device in the channel, the channel having an air inlet upstream of the air movement device in communication with a first region of the enclosure; and,
a pressure chamber in the channel downstream of the air movement device, the air movement device being arranged so as in use to blow air drawn from the air inlet into the pressure chamber, the pressure chamber having an increased resistance to airflow so as to positively pressurise the air flowing therethrough;
the pressure chamber having a first air outlet in communication with a second region of the enclosure and a second air outlet in communication with the exterior of the enclosure.

2. An enclosure according to claim 1, wherein the first and second regions are isolated from each other so as to prevent movement of air between them other than through the channel.

3. An enclosure according to claim 2, wherein said walls perform said isolation.

4. An enclosure according to claim 1, wherein the enclosure has a front face and a rear face, the front face having apertures therein in communication with the first region so that, in use, the air movement device draws cooling air in from the front of enclosure through the apertures, through the first region and into the channel through the air inlet.

5. An enclosure according to claim 4, wherein the second air outlet opens to the exterior of the enclosure at the rear of the enclosure.

6. An enclosure according to claim 4, wherein the air inlet is towards the rear of the enclosure.

7. An enclosure according to claim 6, wherein the first air outlet is closer to the front of the enclosure than the air inlet.

8. An enclosure according to claim 1, wherein the air movement device is arranged so as in use to blow air towards a face of the pressure chamber, causing the air to change direction, thereby causing said increased resistance to airflow.

9. An enclosure according to claim 1, wherein the walls defining the channel are provided by a housing having a generally rectangular box shape, having opposed long side walls, opposed top and bottom walls, and opposed end walls at first and second ends of the housing, the first opening being in one of the long side walls near the first end of the housing, the second opening being in the opposed long side wall at the second end of the housing, the third opening being in the end wall at the first end of the housing, the cooling module comprising a baffle at least partially surrounding the first opening to direct air from the first opening to the air movement device.

10. An enclosure according to claim 9, wherein the air movement device is out of sight behind the baffle and/or the housing.

11. An enclosure according to claim 1, wherein said walls that define the channel, the air movement device and the pressure chamber are provided by a cooling module that is removable from the enclosure.

12. In combination, an enclosure according to claim 1 and a power supply contained within said second region, the power supply having an airflow path from the first air outlet to a vent in the power supply at the rear of the enclosure.

13. A combination according to claim 12, wherein the power supply has an air movement device adjacent its vent for expelling air.

14. In combination, an enclosure according to claim 1 and at least one electronics module contained within said first region, the electronics module having an airflow path in communication with the air inlet.

15. In combination, an enclosure according to claim 1 and at least one disk drive unit, wherein the enclosure has a disk drive enclosure towards the front of the enclosure for receiving said at least one disk drive unit, said first and second regions being accommodated towards the rear of the enclosure.

16. A cooling module for a data storage device enclosure, the cooling module comprising a housing having an air movement device therein, the housing having:
a first opening providing an air inlet, the air movement device being in fluid communication with the air inlet so as to draw air solely via the air inlet;
a pressure chamber constructed and arranged so that the air movement device in use blows air drawn from the air inlet into the pressure chamber, the pressure chamber having an increased resistance to airflow so as to positively pressurise the air in the pressure chamber;
a second opening in fluid communication with the pressure chamber and providing a first air outlet; and,
a third opening in fluid communication with the pressure chamber and providing a second air outlet.

17. A cooling module according to claim 16, constructed and arranged so that the air movement device in use blows air towards a face of the pressure chamber, causing the air to change direction, thereby causing said increased resistance to airflow.

18. A cooling module according to claim 16, wherein the housing has a generally rectangular box shape having opposed long side walls, opposed top and bottom walls, and opposed end walls at first and second ends of the housing, the first opening being in one of the long side walls near the first end of the housing, the second opening being in the opposed long side wall at the second end of the housing, the third opening being in the end wall at the first end of the housing, the cooling module comprising a baffle at least partially surrounding the first opening to direct air from the first opening to the air movement device.

19. A cooling module according to claim 18, wherein the air movement device is out of sight behind the baffle and/or the housing when the cooling module is viewed from the second end.
